(19) United States
(12) Patent Application Publication
(10) Pub. No.: US 2006/0099826 A1
(43) Pub. Date: May 11, 2006

(54) Method of forming an insulation film and semiconductor device having the insulation film

(75) Inventor: Takuo Ohashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/268,635

(22) Filed: Nov. 8, 2005

(30) Foreign Application Priority Data
Nov. 9, 2004 (JP) 2004-324941

(51) Int. Cl. H01L 21/469; H01L 29/78

(52) U.S. Cl. 438/775; 438/791; 257/410; 257/760

(57) ABSTRACT

In a method which forms an insulation film using ALD (Atomic Layer Deposition) and which includes a first step of forming deposited silicon atoms on an objective surface by depositing silicon atoms on the objective surface and a second step of forming a nitride film as the insulation film by nitriding the deposited silicon atoms, the first and the second steps are carried out at a same film forming temperature and a same film forming pressure to lower a flat-band voltage of the nitride film and an interface state density of the nitride film. It is preferable that the film forming temperature is lower than 510 ° C., that the film forming pressure is not higher than 70 Pa, and that an RF power in the second step is not smaller than 0.1 KW. Under these conditions, an insulation film having excellent characteristics including a low flat-band voltage and a low interface state density is obtained. Further, a semiconductor device having the insulation film is obtained.

This application claims priority to prior Japanese patent application JP 2004-324941, the disclosure of which is incorporated herein by reference.

### BACKGROUND OF THE INVENTION

This invention relates to an insulation film for use in a semiconductor device and, in particular, to a method of forming an insulation film by the use of atomic layer deposition (ALD) and a semiconductor device having the insulation film.

A semiconductor device is reduced in device size year by year. Following the reduction in device size, a gate insulation film, for example, is also reduced in thickness. In addition to the reduction in thickness, a demand for film quality characteristics of the gate insulation film becomes more and more strict. Further, each of insulation films used as a mask material and a protection film is also required to be a thinner film and to have an excellent film quality. As those insulation films, an oxide film and a nitride film are predominantly used. In particular, the nitride film is used in a wide variety of semiconductor devices in recent years because the nitride film has a high dielectric constant, a barrier function against impurities, and etching properties different from the oxide film.

In order to form the nitride film, nitrogen or ammonia is used as a nitriding species and various film forming methods are known. For example, use is made of thermal nitriding in which the nitriding species is processed at a high temperature, plasma nitriding in which the nitriding species is excited to create plasma, and so on. In order to produce a thinner film, use is made of atomic layer deposition (ALD) in which single layers of atoms are deposited one layer at a time to form an insulation film.

In case where the nitride film is formed by the ALD, a first step of depositing silicon (Si) atoms and a second step of nitriding the Si atoms are carried out. By repeating the first and the second steps, a desired film thickness is obtained. However, the ALD contains many unknown factors. At present, a nitride film formed by the ALD does not satisfy a required film quality.

Japanese Unexamined Patent Application Publication (JP-A) No. 2004-006455 discloses a technique of improving the film quality of the nitride film formed by the ALD. In the disclosed technique, the nitride film formed by the ALD is annealed by the use of an ammonia gas to thereby improve a dielectric constant. However, many unclear factors are still left as regards a relationship between film forming conditions in the ALD and the film quality of the nitride film formed by the ALD.

As described above, many unclear factors are left as regards the relationship between the film forming conditions in the ALD and the film quality of the nitride film formed by the ALD. In particular, the relationship between the film forming conditions and each of a flat-band voltage (Vfb) and an interface state density (Nss) which are important as film quality characteristics of the insulation film is not clear. Therefore, the insulation film having an excellent film quality is not obtained by the ALD.

### SUMMARY OF THE INVENTION

It is therefore an object of this invention to provide a method capable of forming an insulation film having an optimum flat-band voltage (Vfb) and an optimum interface state density (Nss) and a semiconductor device having the insulation film.

Methods according to this invention and semiconductor devices according to this invention are as follows:

(1) A method of forming an insulation film, the method comprising a first step of forming deposited silicon atoms on an objective surface by depositing silicon atoms on the objective surface and a second step of forming a nitride film as the insulation film by nitriding the deposited silicon atoms, the first and the second steps being carried out at a same film forming temperature and a same film forming pressure.

(2) The method as described in (1), wherein the first and the second steps are carried out at the same film forming temperature and the same film forming pressure to lower a flat-band voltage of the nitride film and an interface state density of the nitride film.

(3) The method as described in (1), wherein the film forming temperature is not lower than 300° C. and is lower than 510° C.

(4) The method as described in (1), wherein the film forming pressure is between 10 and 70 Pa, both inclusive.

(5) The method as described in (1), wherein the second step is carried out at an RF(Radio Frequency) power between 0.1 and 1.0 KW, both inclusive.

(6) The method as described in (1), wherein a dichlorosilane gas is supplied as a supply gas in the first step while an ammonia gas is supplied in the second step.

(7) The method as described in (1), wherein a plurality of cycles each of which comprises the first and the second steps are repeated to form the nitride film having a predetermined thickness.

(8) A semiconductor device comprising as a gate insulation film an insulation film formed by the method described in (7).

(9) A semiconductor device comprising, as a protection film for a metal wiring layer, an insulation film formed by the method described in (7).

In the method of forming an insulation film according to this invention, the ALD having the first step of depositing silicon atoms and the second step of nitriding the silicon atoms is used. The first and the second steps are carried out at the same film forming temperature and the same film forming pressure. The film forming temperature is lower than 510° C. By this method, it is possible to form an insulation film having suitable characteristics including a low flat-band voltage and a low interface state density.

By repeating a cycle of the first and the second steps a plurality of times, a desired film thickness is obtained. It is possible to obtain a semiconductor device comprising the insulation film formed under the above-mentioned film forming conditions and having suitable characteristics including a low flat-band voltage and a low interface state density.

### BRIEF DESCRIPTION OF THE DRAWING

FIG. 1 is a schematic diagram of a film forming apparatus used in this invention;

FIG. 2 is a sectional view of a semiconductor device according to a first embodiment of this invention;

FIG. 3A is a graph showing a relationship between a film forming temperature and a flat-band voltage difference in this invention;

FIG. 3B is a graph showing a relationship between the film forming temperature and an interface state density difference in this invention;

FIG. 4A is a view for describing a film formation mechanism in FIG. 3A;

FIG. 4B is a view for describing a film formation mechanism in FIG. 3B;

FIG. 5A is a graph showing a relationship between a film forming pressure and the flat-band voltage difference in this invention;

FIG. 5B is a graph showing a relationship between the film forming pressure and the interface state density difference in this invention;

FIG. 6A is a graph showing a relationship between an RF power and the flat-band voltage difference in this invention;

FIG. 6B is a graph showing a relationship between the RF power and the interface state density difference in this invention;

FIG. 7 is a graph showing a relationship between the film forming temperature and a hole mobility in this invention; and

FIG. 8 is a sectional view showing a semiconductor device according to a second embodiment of this invention.

### DESCRIPTION OF THE PREFERRED EMBODIMENTS

Now, a method of forming a nitride film by ALD according to this invention will be described with reference to the drawing.

### First Embodiment

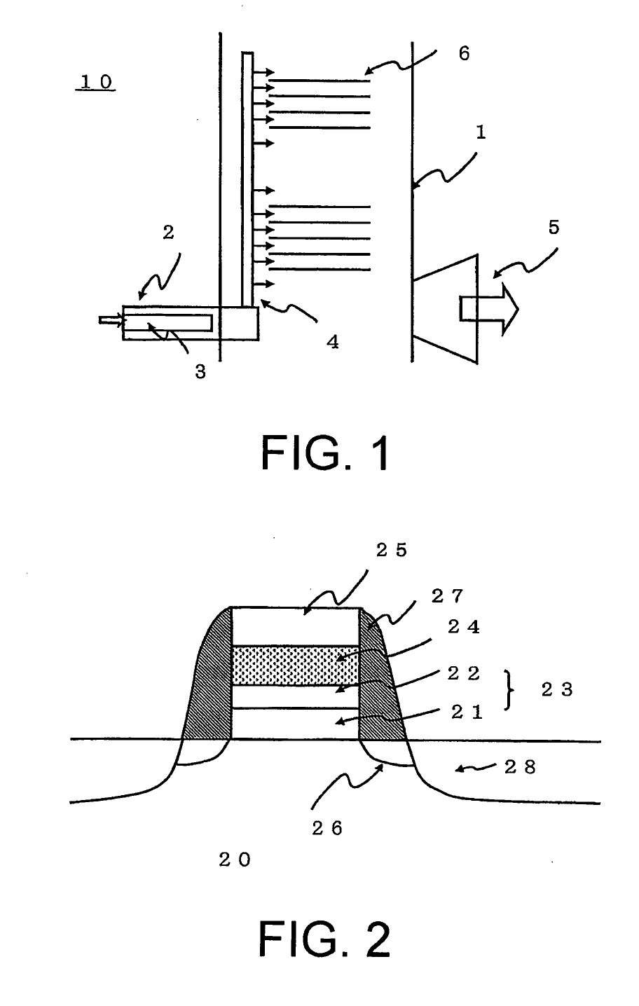

Referring to FIGS. 1 through 7, description will be made about a case where a nitride film formed by ALD is used as a gate insulation film of a semiconductor device.

Referring to FIG. 1, a film forming apparatus 10 is of a batch resistance-heating type and comprises a vertical diffusion furnace 1, a gas injection port 2, an RF plasma portion 3, a gas supply port 4, an exhaust port 5, and a susceptor (not shown) on which a silicon substrate 6 is supported. The diffusion furnace 1 is heated by a heater (not shown) and exhausted through the exhaust port 5. The interior of the diffusion furnace 1 is kept at a predetermined pressure.

Formation of a nitride film by ALD is carried out in the following manner. As a first step, a dichlorosilane (SiH₂CL₂) gas is injected through the gas injection port 2 and uniformly supplied to the silicon substrate 6 through the gas supply port 4. By heating, the SiH₂CL₂ gas is decomposed as represented by SiH₂CL₂−>Si+2HCl. Then, Si atoms are deposited on the silicon substrate 6. The SiH₂CL₂ gas is supplied for about 10 seconds. After deposition of the Si atoms as a one-atom-thick layer or a two-atom-thick layer, the SiH₂CL₂ gas is exhausted. About 10 seconds are required to sufficiently exhaust the SiH₂CL₂ gas. Next, as a second step, an ammonia (NH₃) gas is supplied. The ammonia (NH₃) gas is excited by the RF plasma portion 3 into plasma. The plasma is heated to nitride the Si atoms on the silicon substrate 6. As a consequence, a nitride film is formed on the silicon substrate 6. A residual gas is exhausted.

By repeating a cycle of the first and the second steps a plurality of times, the nitride film having a desired film thickness is formed. For example, in order to form the nitride film having a thickness between 1 nm and 2 nm, 18 to 30 cycles are repeated. In case where the nitride film is deposited on a thermal oxide film as in this embodiment, film formation does not progress in first six cycles and is started around a seventh cycle. Thereafter, the nitride film is formed at a film formation rate of 1 nm/12 cycles. Thus, the nitride film of a desired thickness is obtained in 18 cycles if the thickness is 1 nm and in 30 cycles if the thickness is 2 nm.

In this embodiment, a gate nitride film of a semiconductor device illustrated in FIG. 2 is formed by the use of ALD. Referring to FIG. 2, the semiconductor device is a LDD (Lightly Doped Drain) transistor comprising a silicon substrate 20 on which a gate insulation film 23 composed of a gate oxide film 21 and a gate nitride film 22, a gate electrode 24, a mask insulation film 25 for formation of a gate pattern, and a sidewall insulation film 27 are formed. Further, the silicon substrate 20 is provided with a shallow low-concentration impurity diffusion region 26 self-aligned with the gate insulation film 23 and with the gate electrode 24 and a high-concentration impurity diffusion region 28 self-aligned with the sidewall insulation film 27.

After the gate oxide film 21 is formed by thermal oxidization on the silicon substrate 20 to a thickness of 2 to 3 nm, the gate nitride film 22 is deposited by ALD on the gate oxide film 21 to a thickness of 1 to 2 nm. In the illustrated example, the gate insulation film 23 has a doublelayer structure including the gate oxide film 21 and the gate nitride film 22. Alternatively, the gate insulation film 23 may comprise only the gate nitride film 22. The nitride film 22 was experimentally formed in the following manner. Among film forming conditions of the nitride film 22 by ALD, each of the temperature and the pressure is kept at the same level in the first and the second steps while the remaining conditions are variously changed. By the use of the nitride film 22 as the gate oxide film, the transistor was produced. The nitride film 22 was evaluated for a film quality to reveal the film forming conditions corresponding to excellent film quality characteristics such as a low flat-band voltage and a low interface state density. The results will hereinafter be described.

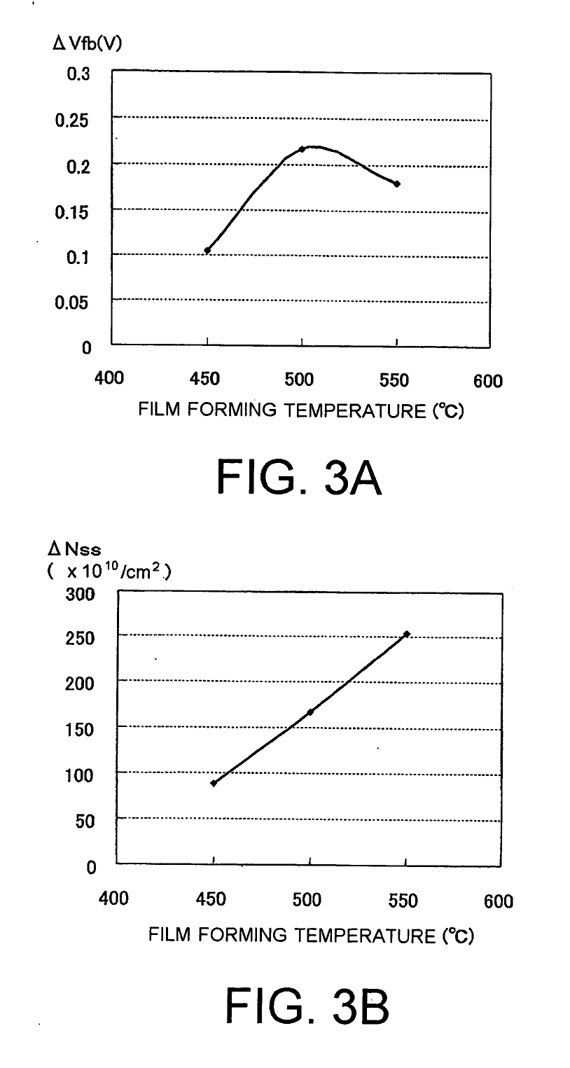

FIG. 3A shows a relationship between a film forming temperature and a flat-band voltage difference [symbol] Vfb and FIG. 3B shows a relationship between the film forming temperature and an interface state density difference [symbol] Nss. Herein, [symbol] Vfb and [symbol] Nss represent the flat-band voltage difference and the interface state density difference as compared with the case where the gate insulation film is entirely formed as the oxide film equivalent in dielectric constant. As these differences are smaller, a flat-band voltage and an interface state density as absolute values are smaller.

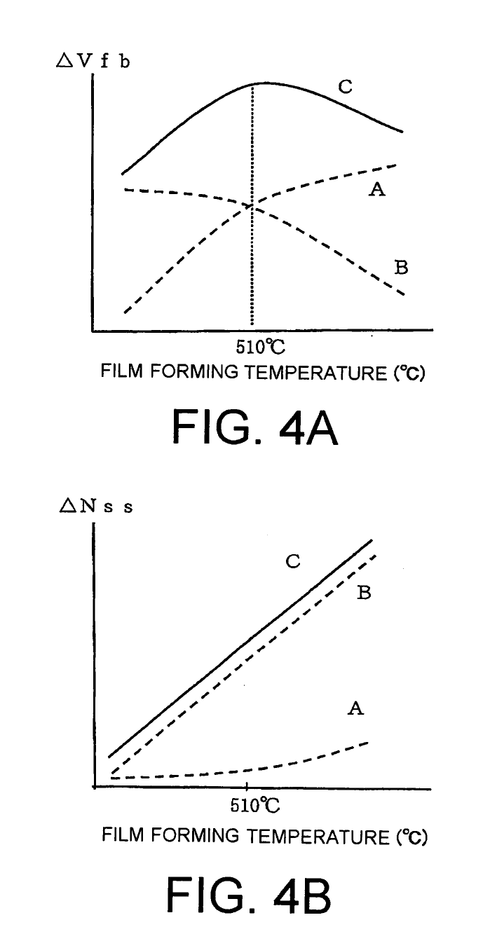

In FIG. 3A, the difference [symbol] Vfb of the flat-band voltage Vfb has a maximum value around the film forming temperature of 510° C. In FIG. 3B, the difference Nss of the interface state density Nss is greater in proportion to the film forming temperature. These mechanisms will be considered with reference to FIGS. 4A and 4B.

The ALD comprises the first step of forming deposited silicon (Si) atoms on an objective surface of an object by depositing silicon atoms on the objective surface and a second step of forming a nitride film as the insulation film by nitriding the deposited silicon atoms. FIGS. 4A and 4B show relationships between the film forming temperature and [symbol] Vfb and [symbol] Nss in these steps. In each figure, curves A and B show the first and the second steps, respectively, and a curve C shows a total dependency upon the film forming temperature.

FIG. 4A shows the relationship between the film forming temperature and the flat-band voltage difference [symbol] Vfb. If the silicon atoms are deposited in the first step at a higher temperature, the composition of the nitride film is deviated from a stoichiometric composition of Si₃N₄ towards a Si-rich side and an amount of charges in the nitride film is increased. As a consequence, the flat-band voltage difference [symbol] Vfb is increased as shown by the curve A. On the other hand, if nitriding in the second step is carried out at a low film forming temperature, nitriding ability is weakened. In this event, the composition is deviated from the stoichiometric composition of Si₃N₄ towards a Si-rich side and an amount of charges in the nitride film is increased. If the film forming temperature is higher, nitriding progresses and the composition approaches to the stoichiometric composition of Si₃N₄. Accordingly, the flat-band voltage difference [symbol] Vfb is reduced as shown by the curve B.

If the first and the second steps are carried out at the same temperature, these phenomena are superposed. The flat-band voltage difference [symbol] Vfb as a total of the first and the second steps is represented by the curve C having a maximum value at 510° C. Therefore, in order to reduce the flat-band voltage difference [symbol] Vfb, the film forming temperature is preferably higher or lower than 510° C.

FIG. 4B shows the relationship between the film forming temperature and the interface state density difference [symbol] Nss. In the first step, if the film forming temperature is high, the interface state density difference is increased but only slightly. Thus, the dependency of the interface state density difference upon the film forming temperature is low as shown in the curve A. In the second step, if the film forming temperature is high, the interface state density difference is significantly increased. This is because, by elevating the temperature, silicon is diffused during nitriding to reach an interface and nitriding occurs. The interface state density difference [symbol] Nss increases in proportion to the film forming temperature as shown by the curve B. The interface state density difference [symbol] Nss as a total of the first and the second steps increases in proportion to the film forming temperature as shown by the curve C. Thus, in order to reduce the interface state density difference [symbol] Nss, the film forming temperature is preferably low.

The film forming temperature is preferably a low temperature lower than 510° C. in order to reduce the flatband voltage difference [symbol] Vfb and the interface state density difference [symbol] Nss. As the film forming temperature is lowered, the film formation rate is reduced and the productivity is decreased. Therefore, preferably, the film forming temperature is not lower than 300° C. as a lower limit. The nitride film formed at the film forming temperature which is not lower than 300° C. and is lower than 510° C. has a small flat-band voltage difference [symbol] Vfb and a small interface state density difference [symbol] Nss. Thus, a film quality approximate to the flat-band voltage Vfb and the interface state density Nss of the oxide film is achieved.

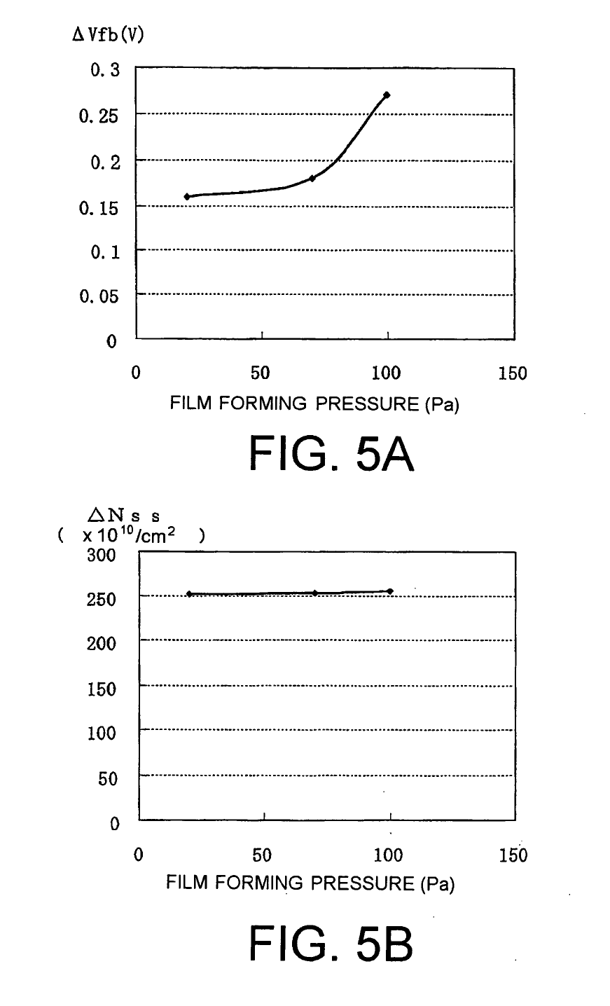

FIG. 5A shows a relationship between a film forming pressure and the flat-band voltage difference [symbol] Vfb. FIG. 5B shows a relationship between the film forming pressure and the interface state density difference [symbol] Nss. With respect to the film forming pressure, the flat-band voltage difference [symbol] Vfb gently increases as the film forming pressure increases in a lower range, and dramatically increases when the film forming pressure exceeds 70 Pa. Therefore, the film forming pressure is, preferably, not greater than 70 Pa. On the other hand, the interface state density difference [symbol] Nss is substantially constant with respect to the film forming pressure and has no dependency upon the film forming pressure. Accordingly, the film forming pressure is, preferably, not greater than 70 Pa in order to reduce the flat-band voltage difference [symbol] Vfb and the interface state density difference [symbol] Nss. If the film forming pressure is excessively low, a long time is required for pressure reduction and the productivity is decreased. Therefore, the film forming pressure is, preferably, not lower than 10 Pa as a lower limit.

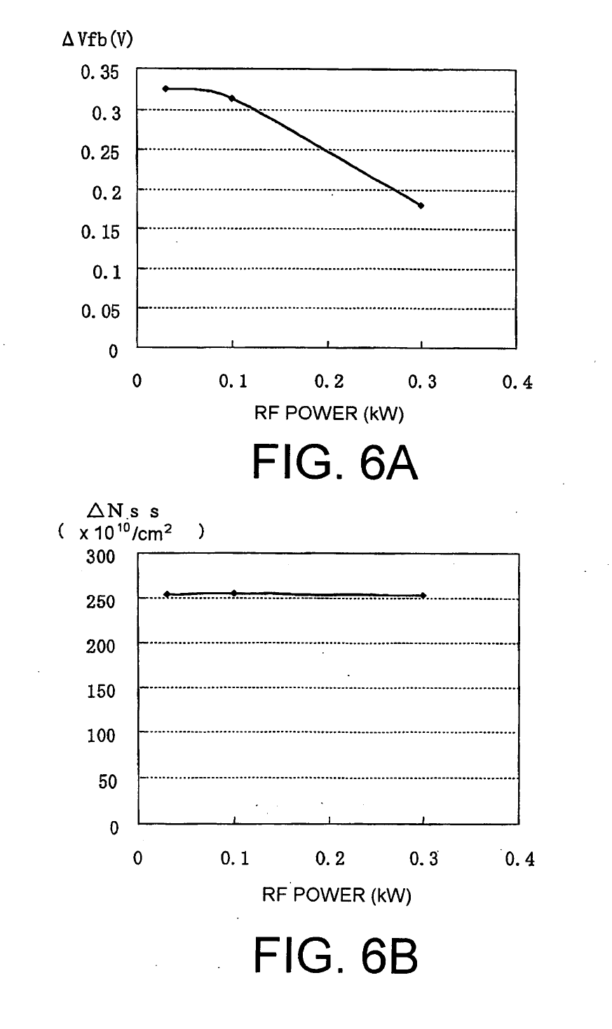

FIG. 6A shows a relationship between an RF power for generating plasma and the flat-band voltage difference [symbol] Vfb. FIG. 6B shows a relationship between the RF power and the interface state density difference [symbol] Nss. With respect to the RF power, the flat-band voltage difference [symbol] Vfb gently decreases as the RF power is increased in a lower range, and drastically decreases when the RF power exceeds 0.1 KW. Therefore, the RF power is, preferably, not lower than 0.1 KW. On the other hand, the interface state density difference [symbol] Nss is substantially constant with respect to the RF power and has no dependency upon the RF power. Accordingly, the RF power is, preferably, not lower than 0.1 KW in order to reduce the flat-band voltage difference [symbol] Vfb and the interface state density difference [symbol] Nss. If the RF power is excessively high, an apparatus cost is elevated. Therefore, the RF power is, preferably, not greater than 1.0 KW as an upper limit.

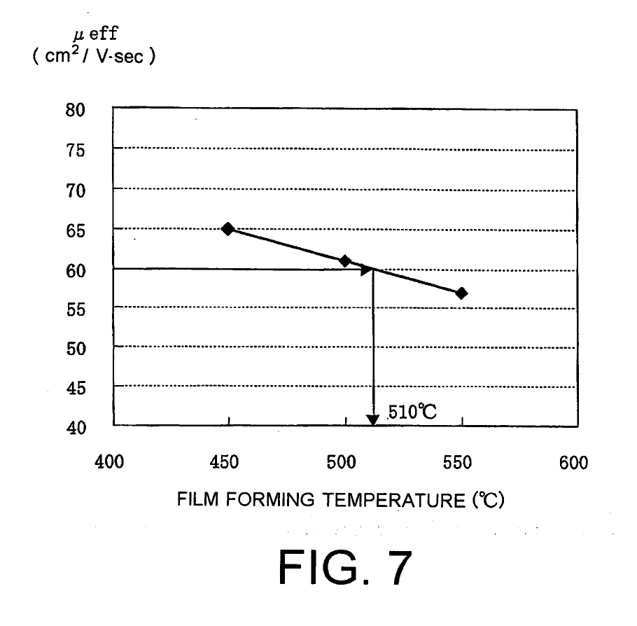

A MOS transistor was produced by forming the gate insulation film of the semiconductor device illustrated in FIG. 2 using the ALD. The relationship between the film forming temperature and a hole mobility (μeff) of a P-channel transistor was measured. The result is shown in FIG. 7. As a measurement condition, a voltage of 0.7 MV/cm was applied.

The hole mobility of the P-channel transistor is inversely proportional to the film forming temperature. The hole mobility (μeff) is greater as the film forming temperature is lower. The hole mobility (μeff) is dependent upon the film forming temperature because of charges (reflected to Vfb) in the insulation film and the level of the interface state density. The hole mobility (μeff) of the P-channel transistor is preferably as large as possible and is desired to be 60 (cm²/V·sec) or more. Accordingly, the film forming temperature is preferably lower than 510° C.

In the method of forming a nitride film by the ALD in this embodiment, optimum conditions for reducing the flat-band voltage Vfb and the interface state density Nss are obtained. The first and the second steps are carried out under the same film forming conditions. The film forming temperature is preferably lower than 510° C. The film forming pressure is, preferably, not greater than 70 Pa. The RF power is, preferably, not lower than 0.1 KW. By repeating a cycle of the first and the second steps a plurality of times, a desired film thickness is obtained. Under the above-mentioned conditions, it is possible to obtain the method capable of forming a nitride film having a small flat-band voltage Vfb and a small interface state density Nss. Further, a large mobility (μeff) is achieved in the transistor comprising as the gate insulation film the insulation film formed under the above-mentioned film forming conditions.

### Second Embodiment

In a second embodiment, a tungsten (W) wire is used as a bit line in a semiconductor device, such as a DRAM, and a nitride film formed by the ALD is used as a protection film for the W wire.

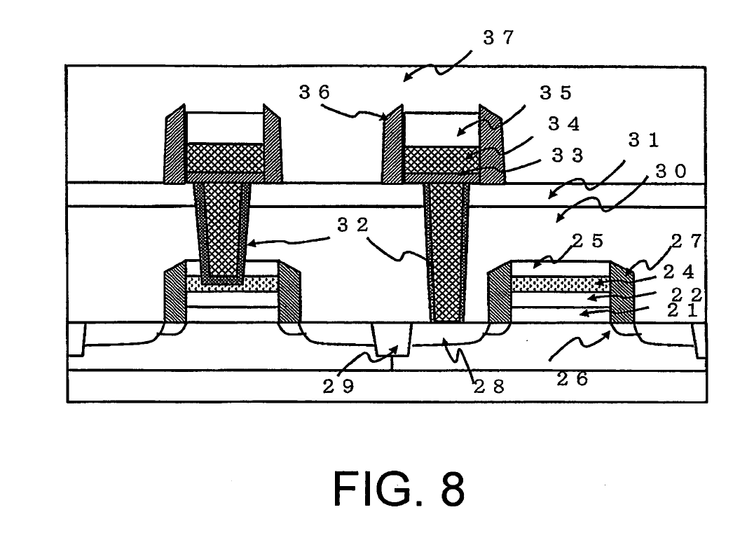

Referring to FIG. 8, the semiconductor device is similar in structure to that illustrated in FIG. 2 until formation of a transistor. Similar parts are designated by like reference numerals and description thereof will be omitted. On a silicon substrate, a transistor is formed in each STI (Shallow Trench Isolation) region isolated by an isolation insulation film 29. The transistor has a low-concentration impurity diffusion region 26 and a high-concentration impurity diffusion region 28. A first interlayer insulation film 30 and a second interlayer insulation film 31 are formed on the silicon substrate. Then, a hole is formed through the first and the second interlayer insulation film 30 and 31 by lithography in order to form a contact plug.

In the hole, Ti/TiN is deposited as a first metal. Then, W as a second metal is filled in the hole. By planarizing the surface using a CMP (Chemical Mechanical Polishing) technique, contact plugs 32 is formed. Herein, the contact plugs 32 are connected to the diffusion region 28 and the gate electrode 24.

On the second insulation film 31 and the upper surface of the contact plug 32 which are planarized, tungsten (W) as a lower conductive layer 33, tungsten nitride (WN) as an upper conductive layer 34, and a mask insulation film 35 for pattern formation are formed. By lithography, a wiring pattern is formed. The lower and the upper conductive layers 33 and 34 are etched using a resist and the mask insulation film 35 to form a metal bit line. Herein, by the ALD under the film forming conditions described in detail in the first embodiment, a nitride film is formed throughout an entire surface of the substrate to a thickness between 1 and 5 nm. As the film forming conditions, the film forming temperature is 450° C., the pressure is 50 Pa, and the RF power is 0.3 KW by way of example. Etching is carried out by an etch-back technique. A nitride film 36 is left only on a side surface of the bit line to cover and protect the metal on the side surface of the bit line. Further, a third interlayer insulation film 37 is formed throughout an entire surface.

By protecting the wire portion with the nitride film formed by the ALD, it is possible to eliminate the influence upon the wire by the formation of the third interlayer insulation film 37. For example, in case where the wire comprises the above-mentioned metal containing tungsten (W), if the wire is directly covered with an insulation film comprising an oxide film, tungsten is oxidized by oxygen during formation of the oxide film so that a resistance of the wiring layer is increased. Further, following the lapse of time, the metal may possibly be corroded by impurities in the oxide film. However, by protecting the metal wire with the nitride film deposited by the ALD and interposed between the interlayer insulation film and the metal wire, the above-mentioned problems are removed.

The nitride film formed by the ALD serves as a barrier against oxygen and impurities. In addition, since the flat-band voltage and the interface state density are small, other elements in the semiconductor device is not adversely affected.

In this embodiment, the semiconductor device is obtained which is capable of preventing deterioration of the metal wiring by protecting the metal wiring with the nitride film formed by the ALD, excellent in flat-band voltage and the interface state density and suitable for reduction in film thickness.

While this invention has thus far been disclosed in conjunction with the preferred embodiments thereof, it will be readily possible for those skilled in the art to put this invention into practice in various other manners within the scope of the appended claims.

What is claimed is:

1. A method of forming an insulation film, said method comprising a first step of forming deposited silicon atoms on an objective surface by depositing silicon atoms on said objective surface and a second step of forming a nitride film as said insulation film by nitriding said deposited silicon atoms, said first and said second steps being carried out at a same film forming temperature and a same film forming pressure.

2. The method as claimed in claim 1, wherein said first and said second steps are carried out at the same film forming temperature and said same film forming pressure to lower a flat-band voltage of said nitride film and an interface state density of said nitride film.

3. The method as claimed in claim 1, wherein said film forming temperature is not lower than 300° C. and is lower than 510° C.

4. The method as claimed in claim 1, wherein said film forming pressure is between 10 and 70 Pa, both inclusive.

5. The method as claimed in claim 1, wherein said second step is carried out at an RF(Radio Frequency) power between 0.1 KW and 1.0 K(W, both inclusive.

6. The method as claimed in claim 1, wherein a dichlorosilane gas is supplied as a supply gas in said first step while an ammonia gas is supplied in said second step.

7. The method as claimed in claim 1, wherein a plurality of cycles each of which comprises said first and said second steps are repeated to form said nitride film having a predetermined thickness.

8. A semiconductor device comprising as a gate insulation film an insulation film formed by the method claimed in claim 7.

9. A semiconductor device comprising, as a protection film for a metal wiring layer, an insulation film formed by the method claimed in claim 7.
